(19) United States
(12) Patent Application Publication
(10) Pub. No.: US 2025/0393115 A1
(43) Pub. Date: Dec. 25, 2025

(54) COOLING MODULE FOR BACKSIDE POWER DELIVERY SYSTEM

(71) Applicant: Wistron Corporation, New Taipei City (TW)

(72) Inventors: Wen-Hua LIU, New Taipei City (TW); Tung-Yang TANG, New Taipei City (TW); Chu-Chia TSAI, New Taipei City (TW)

(21) Appl. No.: 18/934,342

(22) Filed: Nov. 1, 2024

(30) Foreign Application Priority Data
Jun. 25, 2024 (TW) 113123660

(51) Int. Cl. H05K 1/02; H05K 1/14

(52) U.S. Cl. CPC H05K 1/0203; H05K 1/141; H05K 2201/06

(57) ABSTRACT

A cooling technology for a backside power delivery system is provided. In some embodiments, the backside power delivery system includes a substrate, a first electronic component and a second electronic component. The substrate includes a front side and a back side. The first electronic component is arranged on the front side, and the second electronic component is arranged on the back side. A first cooling component is arranged on the first electronic component, and a second cooling component is arranged on the second electronic component. The second electronic component may be a power supply component.

### CROSS-REFERENCE TO RELATED APPLICATION

This non-provisional application claims priority under 35 U.S.C. § 119 (a) to patent application No. 113123660 filed in Taiwan, R.O.C. on Jun. 25, 2024, the entire contents of which are hereby incorporated by reference.

### BACKGROUND

### Technical Field

The present application relates to a cooling module, and in particular, to a cooling module configured for a backside power delivery system.

### Related Art

With the rapid development of Artificial Intelligence, the demand for computational power is increasing exponentially. Concurrently, with the progression of Moore's Law, transistors are becoming smaller, their density is increasing, and the number of stacking layers is growing. Furthermore, existing power delivery technologies, which are typically from the top side (front side) of the chip, may need to pass through 10 to 20 stacked circuit layers to provide power and data signals to transistors located below the chip. This results in an increasingly complex network of wiring layers where power and signal lines coexist. Additionally, during the downward transmission of electrons, IR drop phenomena occur, leading to power loss.

However, with the advent of backside power delivery technology, an effective solution to the aforementioned issues has been provided. The so-called backside power delivery network (BSPDN) technology involves moving the power delivery lines from the original front side of the chip or circuit board to the backside. The primary reason for this shift is that when the process shrinks and the lines become too small, power and signal lines can interfere with each other. By relocating the power lines to the backside of the chip or substrate, separation between power and signal lines can be achieved.

To elaborate further, backside power delivery (BSPDN) technology was first proposed by the Belgian research center IMEC in 2019. It uses nanometer-sized silicon vias (nTSV) structures to connect components on the front side of the wafer to buried power rails. Nanometer-sized silicon vias (nTSV) are high aspect ratio silicon vias that enable connections between the front and backside of the wafer. Additionally, miniaturized fin field-effect transistors (FinFETs) can be interconnected through these buried power rails (BPR).

During development of the related art, for example, an A16 chip manufacturing technology of the Taiwan Semiconductor Manufacturing Company (TSMC), a super power rail architecture is adopted, to arrange a power line configured to deliver power to a transistor at a position below the transistor, a technology known as backside power delivery. This technology facilitates the production of more efficient chips. Specifically, power sources delivered to the source and drain of each transistor use a special contact method that reduces resistance to achieve maximum performance and power efficiency. Additionally, TSMC has developed a backside power delivery technology known as the Buried Power Grid (BPG), which employs a metal grid layer to connect power lines to a structure on the front side of the wafer. According to TSMC, the Buried Power Grid technology can reduce the footprint of power lines by 60%, thereby improving routing efficiency and reducing power consumption.

In addition, the Intel Corporation developed a backside power delivery technology known as “PowerVia.” This technology uses high aspect ratio silicon vias to connect power lines to a structure on the backside of the wafer. According to Intel, the Power Via technology can reduce the footprint of power lines by 50%, thereby improving routing efficiency and reducing power consumption. Additionally, Intel has incorporated this backside power delivery technology into the production process for its Intel 20A chips. This technology not only simplifies power distribution but also allows for more compact chip circuit configurations, with the aim of increasing the number of transistors in the processor to enhance computational power.

Preliminary validation indicates that backside power delivery solutions can enhance the operating frequency of central processing units by approximately 6% and reduce IR drop by about 30%. However, after relocating the power delivery lines to the backside of the substrate, some power supply components, such as voltage regulator modules (VRMs), will also be placed on the backside of the substrate. This introduces a need for thermal management on the backside of the substrate. For instance, with a power supply component (e.g., a VRM) operating at 90% conversion efficiency, 10% of the energy will be dissipated as heat. This means that the backside of the substrate will need to dissipate at least 50 W to 120 W of thermal energy. Therefore, developing technologies for thermal management on the backside of the substrate appears to be an urgent area of focus.

### SUMMARY

In view of the above, the present disclosure provides a cooling module for a backside power delivery system. The backside power delivery system includes a substrate and an electronic component, the electronic component is arranged on a back side of substrate, and the cooling module includes at least one cooling component arranged on the electronic component. The electronic component includes a power supply component.

In some embodiments, the substrate may be a printed circuit board (PCB), and includes another electronic component, and the another electronic component is arranged on a front side of the substrate. The at least one cooling component includes a first cooling component and a second cooling component. The first cooling component and the second cooling component may be fixed to the printed circuit board, and are respectively arranged on the electronic component and the another electronic component.

In some embodiments, the cooling module may further include a plurality of fasteners. The first cooling component may include a plurality of vias, the second cooling component may include a plurality of perforations, and the printed circuit board may include a plurality of through holes. The plurality of fasteners may respectively pass through the plurality of perforations, the plurality of through holes, and the plurality of vias.

In some embodiments, the cooling module may further include a plurality of locking members, and an end of each of the plurality of fasteners may pass through one of the plurality of perforations, one of the plurality of through holes, and one of the plurality of vias, and is locked to one of the plurality of locking members.

In some embodiments, the cooling module may further include a plurality of first fasteners and a plurality of second fasteners. The first cooling component may include a plurality of vias, the second cooling component may include a plurality of first perforations and a plurality of second perforations, and the printed circuit board may include a plurality of through holes. The plurality of first fasteners may respectively pass through the plurality of first perforations, the plurality of through holes, and the plurality of vias. The plurality of second fasteners may respectively pass through the plurality of second perforations and the plurality of through holes.

In some embodiments, the cooling module may further include a bolster plate. The bolster plate may be arranged on the back side of the substrate.

In some embodiments, the another electronic component may be a field-programmable gate array (FPGA), an application-specific integrated circuit (ASIC), a graphics processing unit (GPU), a central processing unit (CPU), a tensor processing unit (TPU), a network processing unit (NPU), or another chip.

In some embodiments, the electronic component may include a voltage regulator module (VRM) or another equivalent element or circuit.

In some embodiments, the first cooling component and the second cooling component each may include a cold plate, a heat sink, a heat pipe, a vapor chamber, a thermal pad, or another equivalent cooling component.

In some embodiments, the cooling module may further include a chip socket. The chip socket may be arranged on the substrate, and the another electronic component may be accommodated in the chip socket.

In some embodiments, the substrate may include a package substrate and a main circuit board. The another electronic component and the electronic component may be respectively arranged on a front side and a back side of the package substrate. The package substrate is electrically connected to the main circuit board, and the package substrate and the main circuit board are spaced apart from each other by a specific distance.

In some embodiments, the cooling module may further include a mezzanine connector. The mezzanine connector may be arranged between the package substrate and the main circuit board, so that the package substrate is electrically connected to the main circuit board and the package substrate and the main circuit board are spaced apart from each other by the specific distance.

In some embodiments, the electronic component may include an integrated voltage regulator or another equivalent element or circuit.

In some embodiments, the main circuit board may include an opening slot. The second cooling component may correspond to the opening slot.

In some embodiments, the cooling module may further include a chip socket. The chip socket may be arranged on the main circuit board, and the package substrate may be accommodated in the chip socket. The chip socket may include a through slot. The second cooling component may correspond to the through slot and the opening slot.

In some embodiments, the package substrate may include an interposer and a packaging substrate. The another electronic component and the electronic component may be respectively arranged on a front side and a back side of the interposer, and the interposer may be electrically connected to the main circuit board through the packaging substrate.

In view of the above, the present disclosure provides a cooling module for a backside power delivery system. The backside power delivery system may include a substrate, a first electronic component, and a second electronic component. The substrate may include a front side and a back side. The first electronic component may be arranged on the front side. The second electronic component may be arranged on the back side. The cooling module may include a first cooling component arranged on the first electronic component and a second cooling component arranged on the second electronic component.

In some embodiments, the substrate may be a printed circuit board. The first cooling component and the second cooling component may be fixed to the printed circuit board. The cooling module may include a plurality of fasteners. The first cooling component may include a plurality of vias, the second cooling component may include a plurality of perforations, and the printed circuit board may include a plurality of through holes. The plurality of fasteners may respectively pass through the plurality of perforations, the plurality of through holes, and the plurality of vias, and two ends of each of the plurality of fasteners may be respectively secured to the first cooling component and the second cooling component.

In view of the above, the present disclosure provides a cooling module for a backside power delivery system. The backside power delivery system may include an interposer, a first electronic component, and a second electronic component. The interposer may include a front side and a back side. The first electronic component may be arranged on the front side. The second electronic component may be arranged on the back side. The cooling module may include a first cooling component arranged on the first electronic component and a second cooling component arranged on the second electronic component. The second electronic component may include an integrated voltage regulator.

In some embodiments, the cooling module may further include a packaging substrate and a main circuit board. The interposer may be electrically connected to the main circuit board through the packaging substrate. The packaging substrate may be spaced apart from the main circuit board by a specific distance.

### BRIEF DESCRIPTION OF THE DRAWINGS

FIG. 1A is an exploded view of a cooling module for a backside power delivery system according to some embodiments of the present disclosure.

FIG. 1B is an exploded view of a cooling module for a backside power delivery system according to some embodiments of the present disclosure.

FIG. 1C is an exploded view of a cooling module for a backside power delivery system according to some embodiments of the present disclosure.

FIG. 1D is an exploded view of a cooling module for a backside power delivery system according to some embodiments of the present disclosure.

FIG. 2A is an exploded view of a cooling module for a backside power delivery system according to some embodiments of the present disclosure.

FIG. 2B is an exploded view of a cooling module for a backside power delivery system according to some embodiments of the present disclosure.

FIG. 2C is an exploded view of a cooling module for a backside power delivery system according to some embodiments of the present disclosure.

FIG. 2D is an exploded view of a cooling module for a backside power delivery system according to some embodiments of the present disclosure.

FIG. 3 is a sectional view of a cooling module for a backside power delivery system according to some embodiments of the present disclosure.

FIG. 4 is a sectional view of a cooling module for a backside power delivery system according to some embodiments of the present disclosure.

FIG. 5 is a sectional view of a cooling module for a backside power delivery system according to some embodiments of the present disclosure.

FIG. 6 is a sectional view of a cooling module for a backside power delivery system according to some embodiments of the present disclosure.

### DETAILED DESCRIPTION

Various embodiments are described in detail below. However, the embodiments are merely used as examples for description, and do not limit or reduce the protection scope of the present disclosure. In addition, some elements are omitted in drawings in the embodiments, to clearly show technical features of the present disclosure. Furthermore, same reference numerals indicate same or similar elements in all of the drawings. The drawings of the present disclosure are merely examples, which are not necessarily drawn to scale, and not all details are necessarily presented in the drawings.

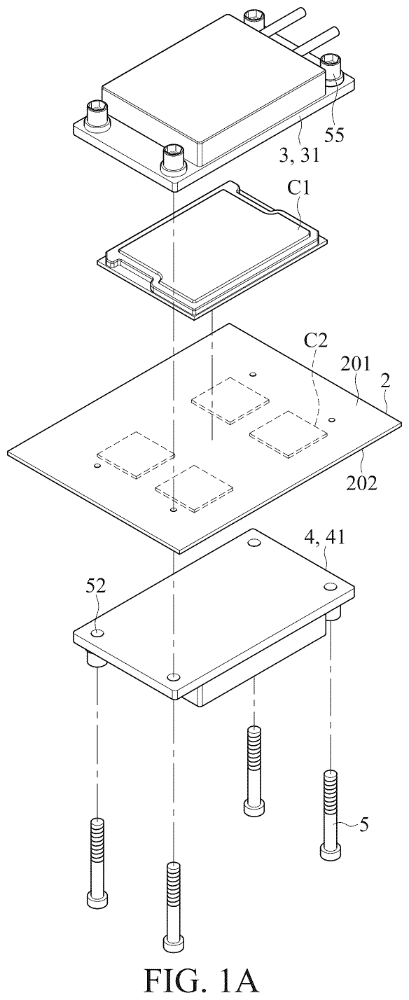

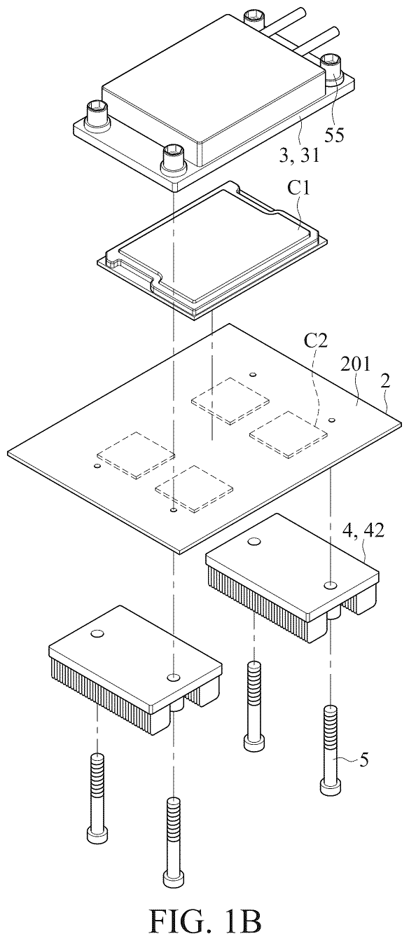

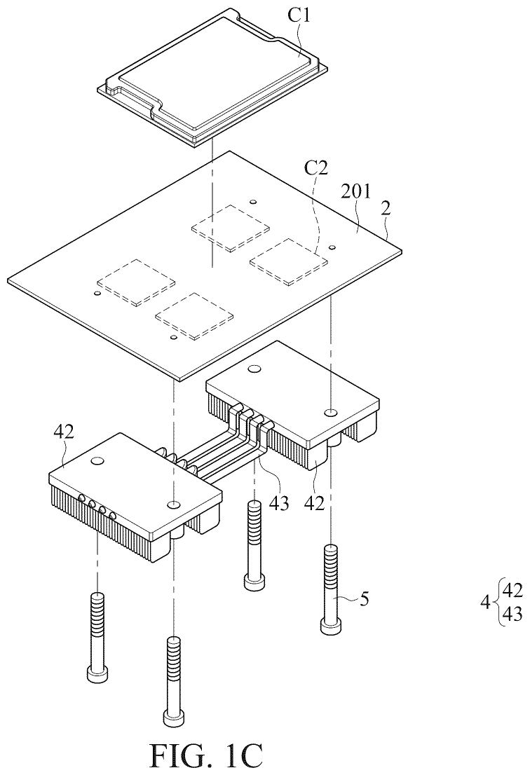

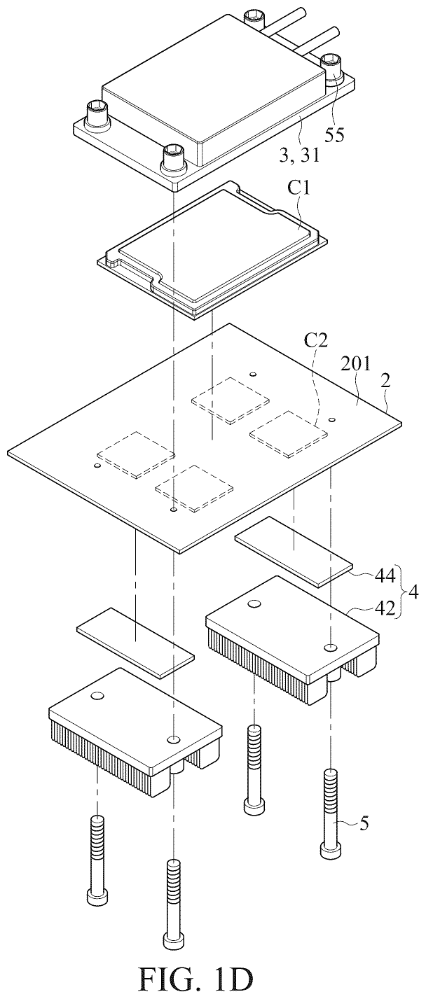

Referring to FIG. 1A, FIG. 1A is an exploded view of a cooling module for a backside power delivery system according to some embodiments of the present disclosure. As shown in the figure, in some embodiments, the backside power delivery system includes a substrate 2, a first electronic component C1, and a second electronic component C2. The first electronic component C1 and the second electronic component C2 are respectively arranged on two corresponding sides, that is, a front side 201 and a back side 202 of the substrate 2. The cooling module includes a first cooling component 3 arranged on the first electronic component C1 and a second cooling component 4 arranged on the second electronic component C2, where the second electronic component C2 includes a power supply component.

Further, in some embodiments, the substrate 2 is a printed circuit board (PCB) 21, with the power delivery lines configured closer to the backside 202 of the substrate 2. Therefore, the second electronic component C2, disposed on the backside 202 of the substrate 2, is a power supply component, such as but not limited to a Voltage Regulator Module (VRM). In addition, the first electronic component C1 arranged on the front side 201 of the substrate 2 may be any electronic component, for example, a field-programmable gate array (FPGA), an application-specific integrated circuit (ASIC), a graphics processing unit (GPU), a central processing unit (CPU), a tensor processing unit (TPU), or a network processing unit (NPU), but the present disclosure is not limited thereto.

In addition, in the embodiment shown in FIG. 1A, the first electronic component C1 and the second electronic component C2 are respectively directly mounted to the front side 201 and the back side 202 of the substrate 2 using Surface-Mount Technology (SMT). Furthermore, as shown in the figure, in some embodiments, the first cooling component 3 and the second cooling component 4 may be a cold plate 31 and a cold plate 41 respectively, and may be in communication with a cooling distribution unit (not shown in the figure). The cooling distribution unit facilitates forced fluid circulation through the cold plate 31 and the cold plate 41 to regulate the temperature of the first cooling component 3 and the second cooling component 4.

As noted, in some embodiments, the first cooling component 3 facilitates heat exchange with the first electronic component C1, while the second cooling component 4 facilitates heat exchange with the second electronic component C2. By continuously forcing the cooling fluid to circulate through the first cooling component 3 and the second cooling component 4, heat generated by the first electronic component C1 and the second electronic component C2 is effectively removed. This helps maintain or even reduce the temperatures of the first electronic component C1 and the second electronic component C2, thereby ensuring optimal operation of the entire system.

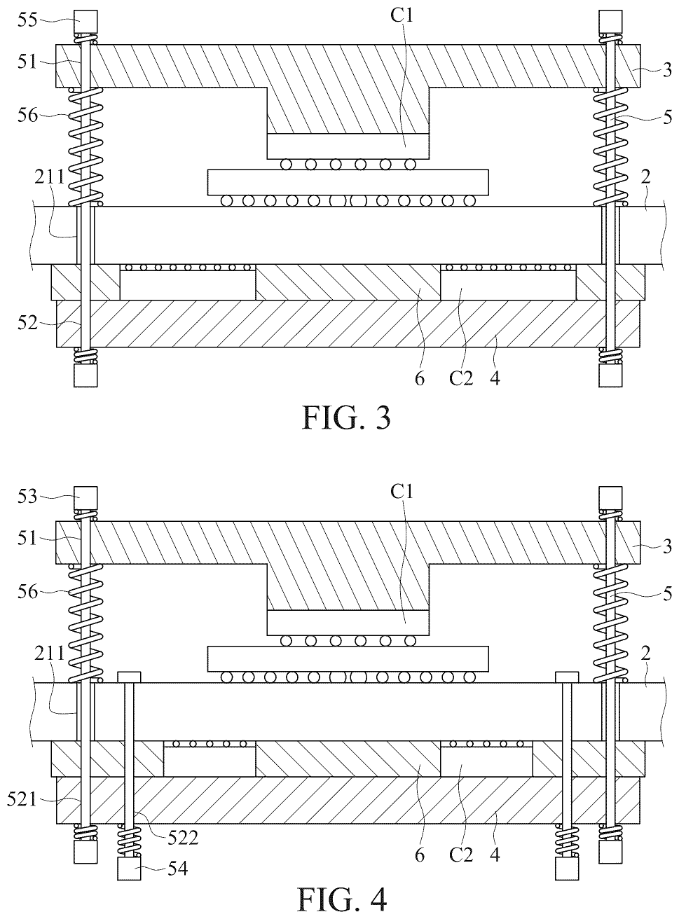

Referring to FIG. 1A and FIG. 3 together, FIG. 3 is a sectional view of a cooling module for a backside power delivery system according to some embodiments of the present disclosure. In some embodiments, the first cooling component 3 and the second cooling component 4 are fixed to the printed circuit board 21. Further, the cooling module may further include a plurality of fasteners 5, such as four fasteners 5. It is preferable that the fasteners 5 are made from metals with good thermal conductivity, such as copper. In addition, the first cooling component 3 includes a plurality of vias 51, for example, four vias 51. The second cooling component 4 includes a corresponding quantity of perforations 52. The printed circuit board 21 includes a corresponding quantity of through holes 211. The fasteners 5 respectively pass through the perforations 52, the through holes 211, and the vias 51.

Further, as shown in the figures, the cooling module may further include a plurality of locking members 55, and a quantity thereof may correspond to the quantity of the fasteners 5, such as four. In some embodiments, each locking member 55 may be a separate member, such as a nut. Alternatively, the locking member 55 may be a threaded section integrated on the first cooling component 3 or the second cooling component 4. Furthermore, an end of each fixing member 5 may pass through a perforation hole 52, a through hole 211, and a via 51, and then secured with the locking member 55. In this way, the first cooling component 3 and the second cooling component 4 can be firmly arranged on two corresponding sides of the substrate 2, and also ensures stable contact with the first electronic component C1 and the second electronic component C2 for effective heat exchange and dissipation.

In addition, in some embodiments, a thermal interface material (TIM) (not shown in the figure) may be further provided between the electronic components and the cooling components, to ensure complete contact between the two contact interfaces. Furthermore, as shown in FIG. 3, a spring 56 may be arranged on each fixing member 5, for example, arranged between the substrate 2 and the first cooling component 3, to achieve buffering. This arrangement creates a cushioning effect to prevent damage to the first electronic component C1 or the substrate 2 due to excessive force during the fastening process.

In some embodiments, the cooling module may further include a bolster plate 6. The bolster plate 6 may be arranged on the substrate 2, and is on a same side as the second electronic component C2. The bolster plate 6 may be made of a hard non-conductive material, such as Bakelite, primarily to enhance the strength of the substrate 2 and reduce the stress experienced by the second electronic component C2.

FIG. 4 is a sectional view of a cooling module for a backside power delivery system according to some embodiments of the present disclosure. FIG. 4 illustrates an alternative method for fixing the first cooling component 3 and the second cooling component 4 compared to the embodiment shown in FIG. 3. In some embodiments, the cooling module may include a plurality of first fasteners 53 and a plurality of second fasteners 54, for example, four first fasteners and four second fasteners. Moreover, the first cooling component 3 includes four vias 51. The second cooling component 4 includes four first perforations 521 and four second perforations 522. The printed circuit board 21 includes four through holes 211.

The four first fasteners 53 respectively pass through the four vias 51, the four through holes 211, and the four first perforations 521. Further, the four second fixing member 54 respectively pass through the four second perforations 522 and the four through holes 211. Thus, in the embodiment shown in FIG. 4, the use of multiple first fasteners 53 and second fasteners 54 allows the second cooling component 4 to be more securely attached to the substrate 2.

In some embodiments, the first fasteners 53 and second fasteners 54 may be made of copper, which has good thermal conductivity. This allows heat from the substrate 2 to be at least partially conducted to the first cooling component 3 and the second cooling component 4. In other words, in addition to dissipating heat from the first electronic component C1 and the second electronic component C2, the first cooling component 3 and the second cooling component 4 can also regulate the temperature of the substrate 2.

FIG. 1B is an exploded view of a cooling module for a backside power delivery system according to some embodiments of the present disclosure. In the embodiment shown in FIG. 1B, the second cooling component 4 arranged on the second electronic component C2 may adopt a heat sink 42. The heat sin is suitable for electronic components with lower Thermal Design Power (TDP). Furthermore, each second electronic component C2 can be equipped with a heat sink 42, or a single heat sink 42 can be shared among multiple second electronic components C2 arranged nearby.

FIG. 1C is an exploded view of a cooling module for a backside power delivery system according to some embodiments of the present disclosure. In some embodiments, the second cooling component 4 arranged on the second electronic component C2 may include a plurality of heat sinks 42 and a plurality of heat pipes 43. In the embodiment shown in FIG. 1C, two heat sinks 42 correspond to two columns of second electronic components C2 arranged separately, and the plurality of heat pipes 43 are connected between the heat sinks 42.

In other embodiments, the heat pipes 43 may be replaced with a vapor chamber (not shown in the figure), or the heat pipes 43 and the vapor chamber are both used simultaneously as heat conduction components. Due to the characteristic of heat pipes 43 to quickly conduct heat, they can maintain the temperature consistency of the heat sinks 42. This allows for the regulation of the thermal design power of various second electronic components C2, maintaining overall better cooling efficiency.

FIG. 1D is an exploded view of a cooling module for a backside power delivery system according to some embodiments of the present disclosure. In some embodiments, the second cooling component 4 may include a plurality of heat sinks 42 and a plurality of thermal pads 44. The thermal pads 44 are generally composed of silicone in combination with thermally conductive powder, providing better thermal conductivity, insulation, and compressibility. In the embodiment shown in FIG. 1D, each heat sink 42 is equipped with a heat thermal pad 44, and the thermal pad 44 is located between the heat sink 42 and the second electronic component C2. The thermal pad 44 is a type of thermal interface material (TIM) used to fill the thermal interface gap formed between a lower surface of the heat sink 42 and an upper surface of the second electronic component C2 during thermal conduction, thereby reducing contact thermal resistance and improving heat transfer efficiency.

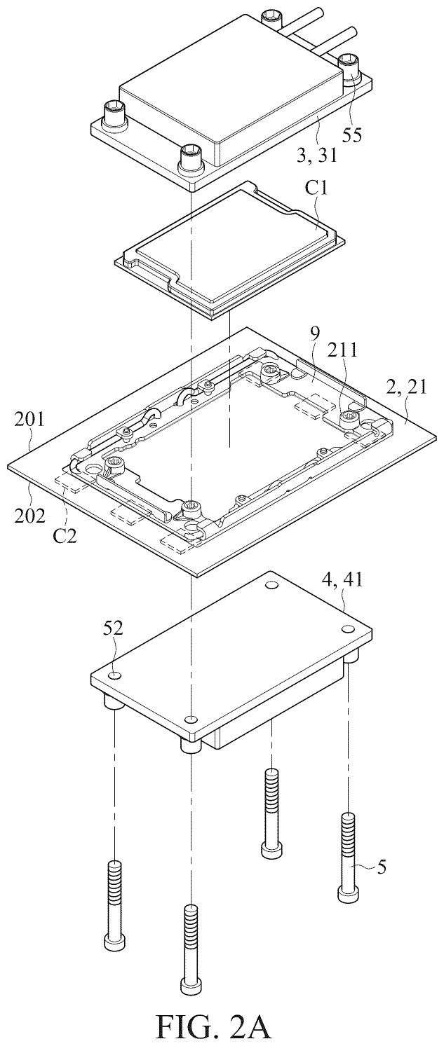

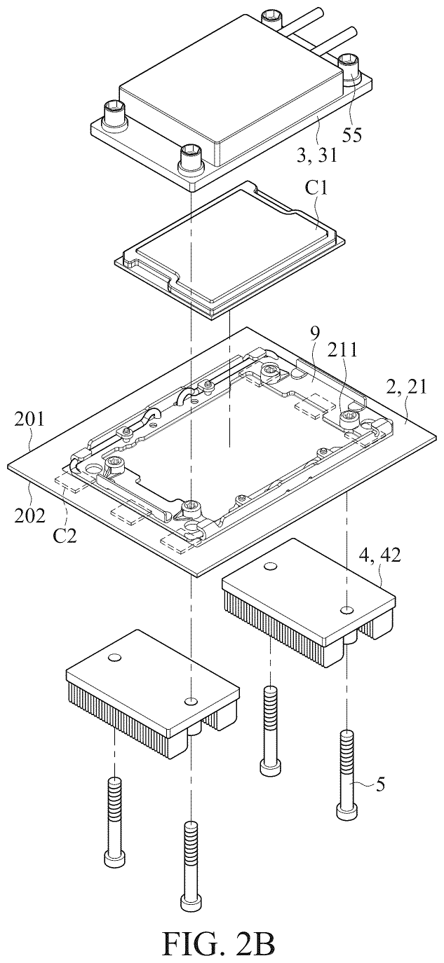

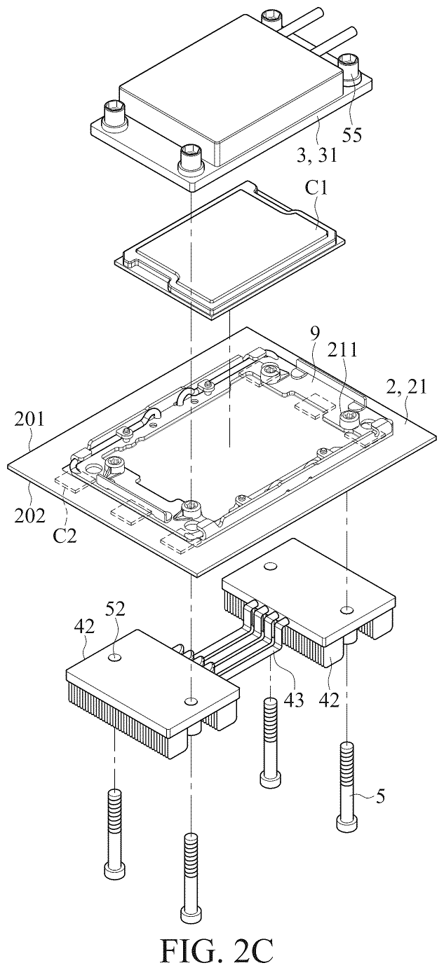

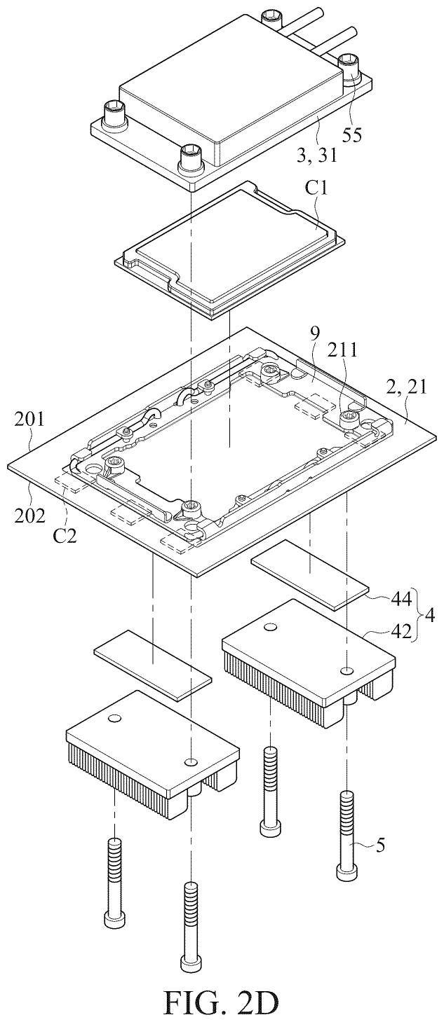

FIG. 2A to FIG. 2D are exploded views of a cooling module for a backside power delivery system according to some embodiments of the present disclosure. Further, the embodiment shown in FIG. 2A to FIG. 2D differs from the embodiment shown in FIG. 1A to FIG. 1D in that a chip socket 9 is arranged on the front side 201 of the substrate 2. The chip socket is configured to accommodate the first electronic component C1. In some embodiments, the chip socket 9 may be an electronic component securing device that integrates an independent loading mechanism (ILM) and a socket. The ILM is generally made of a metal material, and has characteristics of high strength and desirable durability, thus offering better fixation for the first cooling component 3 and the second cooling component 4.

Further, in the embodiment shown in FIG. 2A, the first cooling component 3 and the second cooling component 4 are a cold plate 31 and a cold plate 41 respectively. In the embodiment shown in FIG. 2B, the first cooling component 3 may be a cold plate 31, and the second cooling component 4 may be a heat sink 42. In the embodiment shown in FIG. 2C, the first cooling component 3 is a cold plate 31, and the second cooling component 4 may include a heat sink 42 and a heat pipe 43. In the embodiment shown in FIG. 2D, the first cooling component 3 is a cold plate 31, and the second cooling component 4 may include a heat sink 42 and a thermal pad 44.

In addition, in some embodiments, the chip socket 9 includes the metal ILM, and the fixing member 5 adopts the copper post. Since the metal ILM and the copper post have a desirable thermal conductivity, when the temperature of the substrate 2 increases, the metal ILM and the copper post can appropriately transfer the heat from the substrate 2 to the first cooling component 3 and the second cooling component 4, and the heat is dissipated through the first cooling component 3 and the second cooling component 4, thereby cooling the substrate 2.

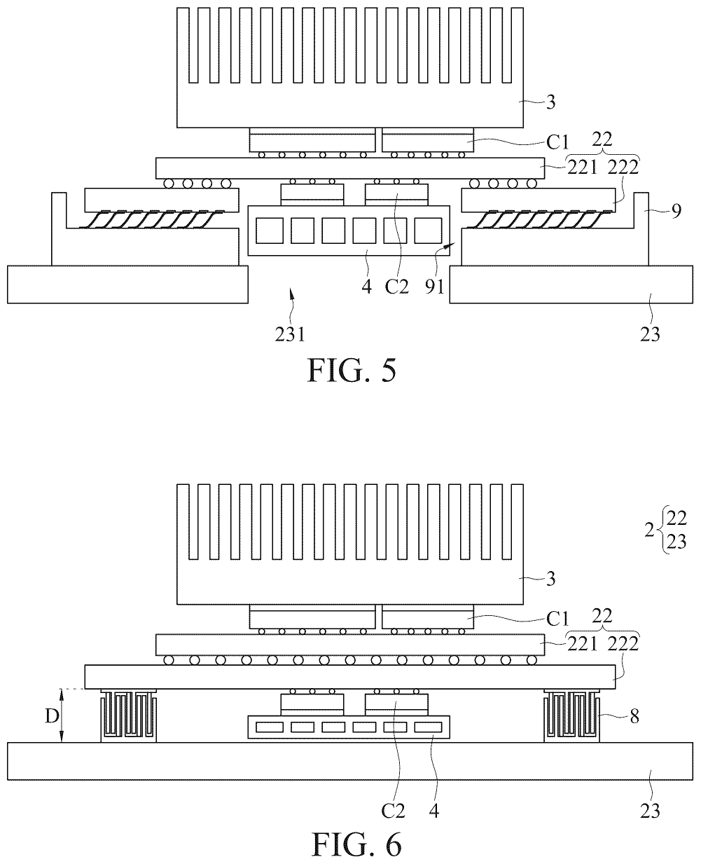

Referring FIG. 5, FIG. 5 is a sectional view of a cooling module for a backside power delivery system according to some embodiments of the present disclosure. In the embodiment shown in FIG. 5, the substrate 2 may include a package substrate 22 and a main circuit board 23. The package substrate 22 includes an interposer 221 and a packaging substrate 222. The first electronic component C1 is arranged on a front side 201 of the interposer 221, and the second electronic component C2 is arranged on a back side 202 of the interposer 221.

In addition, the first cooling component 3 is arranged on the first electronic component C1, which is on one side of the interposer 221. The second cooling component 4 is arranged on the second electronic component C2, which is on the other side of the interposer 221. In some embodiments, the first electronic component C1 may be an FPGA, an ASIC, a GPU, a CPU, a TPU, or an NPU, and the second electronic component C2 may include an integrated voltage regulator.

Furthermore, as shown in FIG. 5, the interposer 221 is electrically connected to the main circuit board 23 through the packaging substrate 222. In some embodiments, a chip socket 9 is arranged on the main circuit board 23. The entire package substrate 22 is accommodated in the chip socket 9, and the packaging substrate 222 is electrically connected to the main circuit board 23 through a land grid array (LGA) within the chip socket 9. In other embodiments, the packaging substrate 222 may be electrically connected to the main circuit board 23 through a pin grid array (PGA) or a ball grid array (BGA).

Furthermore, the main circuit board 23 includes an opening slot 231, the chip socket 9 includes a through slot 91, and the second cooling component 4 corresponds to the opening slot 231 and the through slot 91. In this way, the second cooling component 4 can be accommodated in the opening slot 231 and the through slot 91. In addition, through the opening slot 231 and the through slot 91, the second cooling component 4 can extend beyond the main circuit board 23. For example, the second cooling component 4 can be a heat sink or a cold plate, and can be used in combination with a heat pipe, a vapor chamber, or a thermal pad (not shown in the figure). In this configuration, the heat sinks and cold plates can be mounted on or around the main circuit board 23, while one end of the heat pipes, vapor chambers, or thermal pads contacts the second electronic component C2, and the other end connects to the heat sinks or cold plates.

Referring FIG. 6, FIG. 6 is a sectional view of a cooling module for a backside power delivery system according to some embodiments of the present disclosure. In the embodiment shown in FIG. 6, the substrate 2 includes a package substrate 22 and a main circuit board 23, and the package substrate 22 includes an interposer 221 and a packaging substrate 222. The first electronic component C1 and the second electronic component C2 are respectively arranged on opposite sides of the package substrate 22. Specifically, the first electronic component C1 is arranged on a front side of the interposer 221, while the second electronic component C2 is arranged on a back side of the packaging substrate 222. Furthermore, the interposer 221 is electrically connected to the main circuit board 23 through the packaging substrate 222.

In addition, in the embodiment shown in FIG. 6, the package substrate 22 is electrically connected to the main circuit board 23 through a mezzanine connector 8, and the package substrate 22 is spaced apart from the main circuit board 23 by the specific distance D. In other embodiments, the package substrate 22 may be electrically connected to the main circuit board 23 using alternative methods, and the package substrate 22 is spaced apart from the main circuit board 23 by a specific distance D in another manner, such as isolation support pillars, to maintain the specific distance D. In some embodiments, this distance D can be used to accommodate the second electronic component C2 and the second cooling component 4

Although the present application has been described in considerable detail with reference to certain preferred embodiments thereof, the disclosure is not for limiting the scope of the application. Persons having ordinary skill in the art may make various modifications and changes without departing from the scope and spirit of the application. Therefore, the scope of the appended claims should not be limited to the description of the preferred embodiments described above.

What is claimed is:

1. A cooling module for a backside power delivery system, wherein the backside power delivery system comprises a substrate and an electronic component, the electronic component is arranged on a back side of the substrate, and the cooling module comprises:
at least one cooling component, arranged on the electronic component; and
the electronic component comprises a power supply component.

2. The cooling module for a backside power delivery system according to claim 1, wherein the substrate is a printed circuit board (PCB), and comprises another electronic component, the another electronic component is arranged on a front side of the substrate, the at least one cooling component comprises a first cooling component and a second cooling component, and the first cooling component and the second cooling component are fixed to the printed circuit board, and are respectively arranged on the electronic component and the another electronic component.

3. The cooling module for a backside power delivery system according to claim 2, further comprising a plurality of fasteners, wherein the first cooling component comprises a plurality of vias, the second cooling component comprises a plurality of perforations, the printed circuit board comprises a plurality of through holes, and the plurality of fasteners respectively pass through the plurality of perforations, the plurality of through holes, and the plurality of vias.

4. The cooling module for a backside power delivery system according to claim 3, further comprising a plurality of locking members, wherein an end of each of the plurality of fasteners passes through one of the plurality of perforations, one of the plurality of through holes, and one of the plurality of vias, and is locked to one of the plurality of locking members.

5. The cooling module for a backside power delivery system according to claim 2, further comprising a plurality of first fasteners and a plurality of second fasteners, wherein the first cooling component comprises a plurality of vias, the second cooling component comprises a plurality of first perforations and a plurality of second perforations, the printed circuit board comprises a plurality of through holes, the plurality of first fasteners respectively pass through the plurality of first perforations, the plurality of through holes, and the plurality of vias, and the plurality of second fasteners respectively pass through the plurality of second perforations and the plurality of through holes.

6. The cooling module for a backside power delivery system according to claim 2, further comprising a bolster plate, wherein the bolster plate is arranged on the back side of the substrate.

7. The cooling module for a backside power delivery system according to claim 2, wherein the another electronic component comprises one selected from a group consisting of a field-programmable gate array (FPGA), an application-specific integrated circuit (ASIC), a graphics processing unit (GPU), a central processing unit (CPU), a tensor processing unit (TPU), and a network processing unit (NPU).

8. The cooling module for a backside power delivery system according to claim 2, wherein the electronic component comprises a voltage regulator module (VRM).

9. The cooling module for a backside power delivery system according to claim 2, wherein the first cooling component and a second cooling component each comprise one selected from a group consisting of a cold plate, a heat sink, a heat pipe, a vapor chamber, and a thermal pad.

10. The cooling module for a backside power delivery system according to claim 2, further comprising a chip socket, wherein the chip socket is arranged on the substrate, and the another electronic component is accommodated in the chip socket.

11. The cooling module for a backside power delivery system according to claim 2, wherein the substrate comprises a package substrate and a main circuit board, the another electronic component and the electronic component are respectively arranged on a front side and a back side of the package substrate, the package substrate is electrically connected to the main circuit board, and the package substrate and the main circuit board are spaced apart from each other by a specific distance.

12. The cooling module for a backside power delivery system according to claim 11, further comprising a mezzanine connector, wherein the mezzanine connector is arranged between the package substrate and the main circuit board, so that the package substrate is electrically connected to the main circuit board and the package substrate and the main circuit board are spaced apart from each other by the specific distance.

13. The cooling module for a backside power delivery system according to claim 11, wherein the electronic component comprises an integrated voltage regulator.

14. The cooling module for a backside power delivery system according to claim 11, wherein the main circuit board comprises an opening slot, and the second cooling component corresponds to the opening slot.

15. The cooling module for a backside power delivery system according to claim 14, further comprising a chip socket, wherein the chip socket is arranged on the main circuit board, the package substrate is accommodated in the chip socket, the chip socket comprises a through slot, and the second cooling component corresponds to the through slot and the opening slot.

16. The cooling module for a backside power delivery system according to claim 11, wherein the package substrate comprises an interposer and a packaging substrate, the another electronic component and the electronic component are respectively arranged on a front side and a back side of the interposer, and the interposer is electrically connected to the main circuit board through the packaging substrate.

17. A cooling module for a backside power delivery system, wherein the backside power delivery system comprises a substrate, a first electronic component, and a second electronic component, the substrate comprises a front side and a back side, the first electronic component is arranged on the front side, the second electronic component is arranged on the back side, and the cooling module comprises:
a first cooling component, arranged on the first electronic component; and
a second cooling component, arranged on the second electronic component.

18. The cooling module for a backside power delivery system according to claim 17, wherein the substrate is a printed circuit board, the first cooling component and the second cooling component are fixed to the printed circuit board, the cooling module comprises a plurality of fasteners, the first cooling component comprises a plurality of vias, the second cooling component comprises a plurality of perforations, the printed circuit board comprises a plurality of through holes, the plurality of fasteners respectively pass through the plurality of perforations, the plurality of through holes, and the plurality of vias, and two ends of each of the plurality of fasteners are respectively secured to the first cooling component and the second cooling component.

19. A cooling module for a backside power delivery system, wherein the backside power delivery system comprises an interposer, a first electronic component, and a second electronic component, the interposer comprises a front side and a back side, the first electronic component is arranged on the front side, the second electronic component is arranged on the back side, and the cooling module comprises:
a first cooling component, arranged on the first electronic component; and
a second cooling component, arranged on the second electronic component; and
the second electronic component comprises an integrated voltage regulator.

20. The cooling module for a backside power delivery system according to claim 19, further comprising a packaging substrate and a main circuit board, wherein the interposer is electrically connected to the main circuit board through the packaging substrate, and the packaging substrate is spaced apart from the main circuit board by a specific distance.
